(19) United States
(12) Patent Application Publication
(10) Pub. No.: US 2011/0128423 A1
(43) Pub. Date: Jun. 2, 2011

(54) IMAGE SENSOR AND METHOD OF MANUFACTURING THE SAME

(76) Inventors: Myung-Bok LEE, (US); Sang-Chul Sul, (US); Young-Gu Jin, (US)

(21) Appl. No.: 12/944,272

(22) Filed: Nov. 11, 2010

(30) Foreign Application Priority Data
Dec. 2, 2009 (KR) 10-2009-0118150

(51) Int. Cl. H04N 5/335

(52) U.S. Cl. 348/294; 348/E05.091

(57) ABSTRACT

An image sensor includes a plurality of color sensors, a plurality of depth sensors, a near-infrared cut filter, a color filter, a pass filter and a rejection filter. The color sensors and depth sensors are formed on a substrate. The near-infrared cut filter and the color filter are formed on the color sensors. The pass filter is formed on the depth sensors, and is adapted to transmit light having a wavelength longer than an upper limit of a visible light wavelength. The pass filter has a multi-layer structure wherein a semiconductor material and a semiconductor oxide material are alternately stacked. The rejection filter is formed over the near-infrared cut filter, the color filter and the pass filter, and is adapted to transmit light having a wavelength shorter than an upper limit of a near-infrared light wavelength.

### CROSS-REFERENCE TO RELATED APPLICATION

This application claims priority under 35 USC §119 to Korean Patent Application No. 10-2009-0118150, filed on Dec. 2, 2009, the disclosure of which is hereby incorporated by reference herein in its entirety.

### BACKGROUND

1. Technical Field

The inventive concept relates generally to image sensors. More particularly, the inventive concept relates to a three-dimensional color image sensor providing image information and depth information within a single chip and a method of manufacturing the image sensor.

2. Description of the Related Art

A complementary metal-oxide semiconductor (CMOS) image sensor may provide two-dimensional color image information, and a depth sensor may provide three-dimensional information, or depth information. Since the depth sensor uses infrared light as a light source, the depth sensor may provide only the depth information and black-and-white image information, and may not provide the color image information.

Accordingly, a three-dimensional color image sensor may be required, which can provide the color image information and the depth information within a single chip. To implement the three-dimensional color image sensor, a wavelength of light incident on a color sensor region should be different from a wavelength of light incident on a depth sensor region. That is, only visible light should be incident on the color sensor region, and only infrared light should be incident on the depth sensor region. However, it may be complicated to allow lights of different wavelengths to enter corresponding regions within a single chip

Thus, there is a need in the art for a three-dimensional color image sensor providing image information and depth information within a single chip and to a method of manufacturing the image sensor.

### SUMMARY

Example embodiments may provide an image sensor that provides color image information and depth information within a single chip.

Example embodiments may provide a method of manufacturing an image sensor that provides color image information and depth information within a single chip.

According to example embodiments, an image sensor includes a plurality of color sensors, a plurality of depth sensors, a near-infrared cut filter, a color filter, a pass filter and a rejection filter. The color sensors and the depth sensors are formed on a substrate. The near-infrared cut filter and the color filter are formed on the color sensors. The pass filter is formed on the depth sensors. The pass filter is adapted to transmit light having a wavelength longer than an upper limit of a visible light wavelength. The pass filter has a multi-layer structure wherein a semiconductor material and a semiconductor oxide material are alternately stacked. The rejection filter is formed over the near-infrared cut filter, the color filter and the pass filter. The rejection filter is adapted to transmit light having a wavelength shorter than an upper limit of a near-infrared light wavelength.

In some embodiments, the semiconductor material may include silicon, and the semiconductor oxide material may include silicon oxide.

In some embodiments, the multi-layer structure may include three through ten layers, and may have a thickness ranging from about 200 nm to about 1,000 nm. Each layer included in the multi-layer structure may have a thickness lower than about 200 nm.

In some embodiments, the pass filter may transmit light having a wavelength ranging from about 800 nm to about 900 nm.

In other embodiments, the pass filter may transmit light having a wavelength longer than about 800 nm.

In some embodiments, the near-infrared cut filter may have a photonic crystal structure including at least two materials having different refractive indexes. The at least two materials may include silicon and silicon oxide.

In some embodiments, the near-infrared cut filter may include a silicon pillar array including a plurality of silicon pillars that are periodically arranged, and a silicon oxide matrix filling spaces between the silicon pillars with silicon oxide.

In other embodiments, the near-infrared cut filter may include a silicon oxide pillar array including a plurality of silicon oxide pillars that are periodically arranged, and a silicon matrix filling spaces between the silicon oxide pillars with silicon.

In some embodiments, the near-infrared cut filter may be formed on the color filter.

In other embodiments, the near-infrared cut filter may be formed beneath the color filter.

In a method of manufacturing an image sensor according to example embodiments, a plurality of color sensors and a plurality of depth sensors are formed on a substrate. A near-infrared cut filter and a color filter are formed on the color sensors. A pass filter is formed on the depth sensors. The pass filter is adapted to transmit light having a wavelength longer than an upper limit of a visible light wavelength, and has a multi-layer structure wherein a semiconductor material and a semiconductor oxide material are alternately stacked. A rejection filter is formed over the near-infrared cut filter, the color filter and the pass filter. The rejection filter is adapted to transmit light having a wavelength shorter than an upper limit of a near-infrared light wavelength.

To form the pass filter, a silicon layer and a silicon oxide layer may be alternately stacked on the color sensors and the depth sensors, and the silicon layer and the silicon oxide layer on the color sensors may be removed. The number of the stacked silicon and silicon oxide layers may be three through ten. The pass filter may have a thickness ranging from about 200 nm to about 1,000 nm. Each of the silicon layer and the silicon oxide layer may have a thickness lower than about 200 nm.

The near-infrared cut filter may have a photonic crystal structure including at least two materials having different refractive indexes.

In some embodiments, to form the near-infrared cut filter, a plurality of periodic silicon pillars may be formed on the color sensors, and spaces between the silicon pillars may be filled with silicon oxide.

In other embodiments, to form the near-infrared cut filter, a silicon layer may be formed on the color sensors, periodic holes may be formed in the silicon layer, and the holes may be filled with silicon oxide.

Accordingly, the image sensor according to example embodiments can provide three-dimensional color images. Further, the image sensor can be manufactured with simple processes. The color image sensor may be applied to devices, such as a camera, and may provide realistic images.

### BRIEF DESCRIPTION OF THE DRAWINGS

Example embodiments will be more clearly understood from the following detailed description taken in conjunction with the accompanying drawings.

FIG. 1 is a diagram illustrating a three-dimensional color image sensor in accordance with an exemplary embodiment of the present inventive concept.

FIG. 2 is a cross-sectional view of a three-dimensional color image sensor illustrated in FIG. 1.

FIG. 3 is a graph illustrating spectrum characteristics of filters included in a three-dimensional color image sensor illustrated in FIG. 1.

FIG. 4 is a perspective view of a near-infrared (NIR) cut filter included in a three-dimensional color image sensor illustrated in FIG. 1.

FIG. 5 is a diagram illustrating an arrangement of filters included in a three-dimensional color image sensor illustrated in FIG. 1.

FIGS. 6 through 10 are cross-sectional views for illustrating a method of manufacturing a three-dimensional color image sensor illustrated in FIG. 2.

FIG. 11 is a graph illustrating a spectrum characteristic of a NIR band pass filter of a first sample.

FIG. 12 is a graph illustrating a spectrum characteristic of a NIR band pass filter of a second sample.

FIG. 13 is a cross-sectional view of a three-dimensional color image sensor in accordance with an exemplary embodiment of the present inventive concept.

FIGS. 14 and 15 are cross-sectional views for illustrating a method of manufacturing a three-dimensional color image sensor illustrated in FIG. 13.

FIG. 16 is a cross-sectional view of a three-dimensional color image sensor in accordance with an exemplary embodiment of the present inventive concept.

FIG. 17 is a perspective view of a NIR cut filter included in a three-dimensional color image sensor illustrated in FIG. 16.

FIGS. 18 and 19 are cross-sectional views for illustrating a method of manufacturing a three-dimensional color image sensor illustrated in FIG. 16.

FIG. 20 is a cross-sectional view of a three-dimensional color image sensor in accordance with an exemplary embodiment of the present inventive concept.

FIG. 21 is a graph illustrating spectrum characteristics of filters included in a three-dimensional color image sensor illustrated in FIG. 20.

FIG. 22 is a graph illustrating a spectrum characteristic of a long wave pass filter of a third sample.

FIG. 23 is a graph illustrating spectrum characteristics of long wave pass filters of which the numbers of layers are different from each other.

FIG. 24 is a diagram illustrating a mobile phone including a three-dimensional color image sensor that provides depth information as well as image information.

FIG. 25 is a block diagram illustrating a system including a three-dimensional color image sensor that provides depth information as well as image information.

### DETAILED DESCRIPTION OF THE EXEMPLARY EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

### Embodiment 1

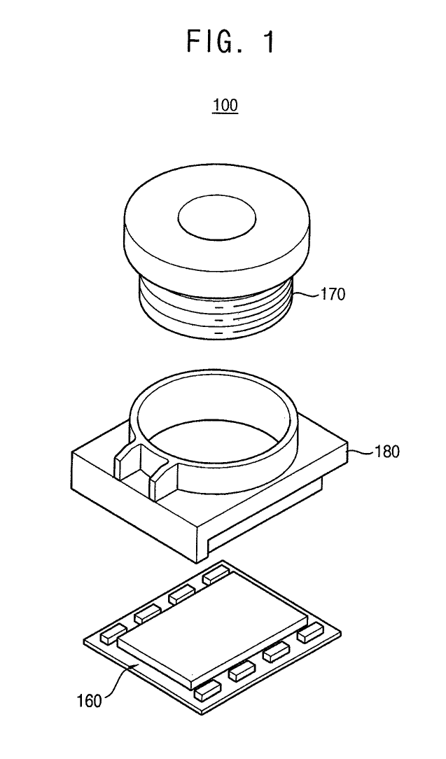

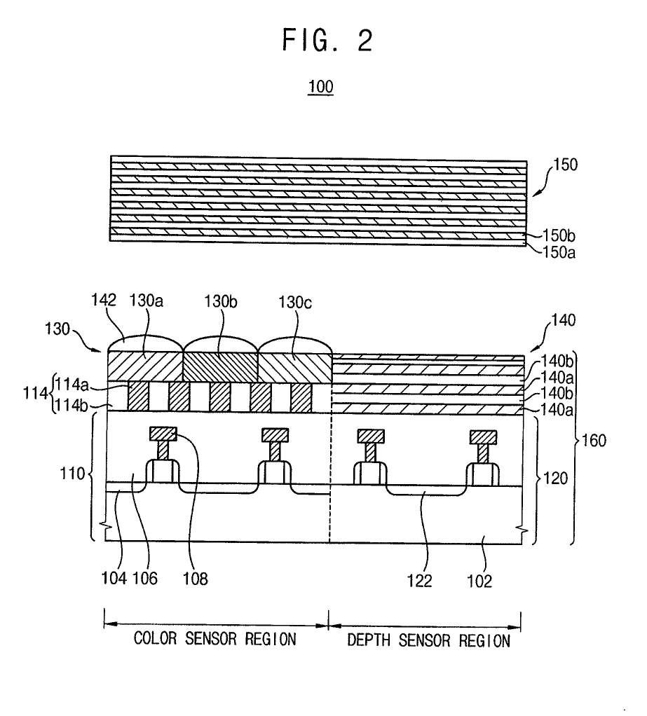

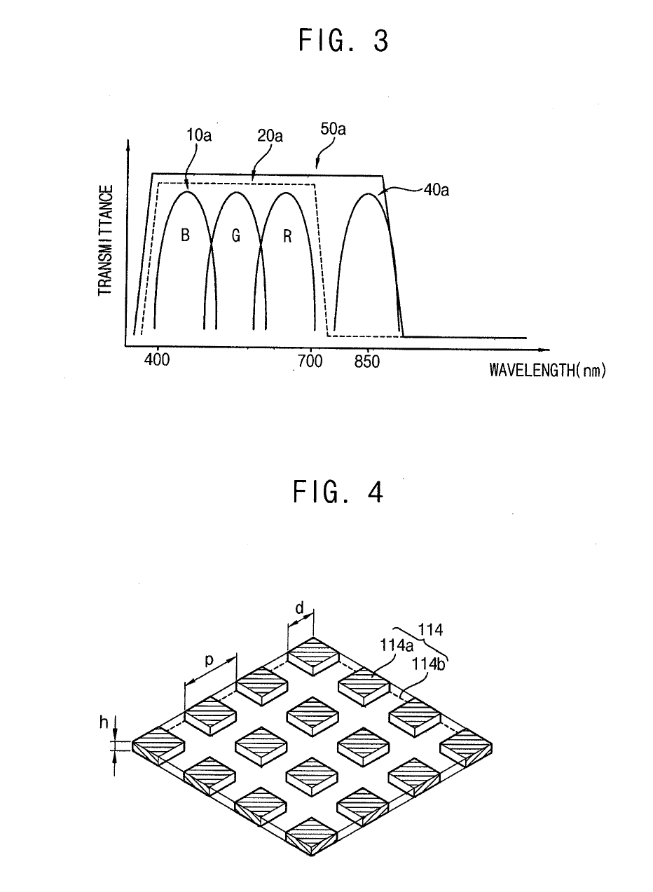

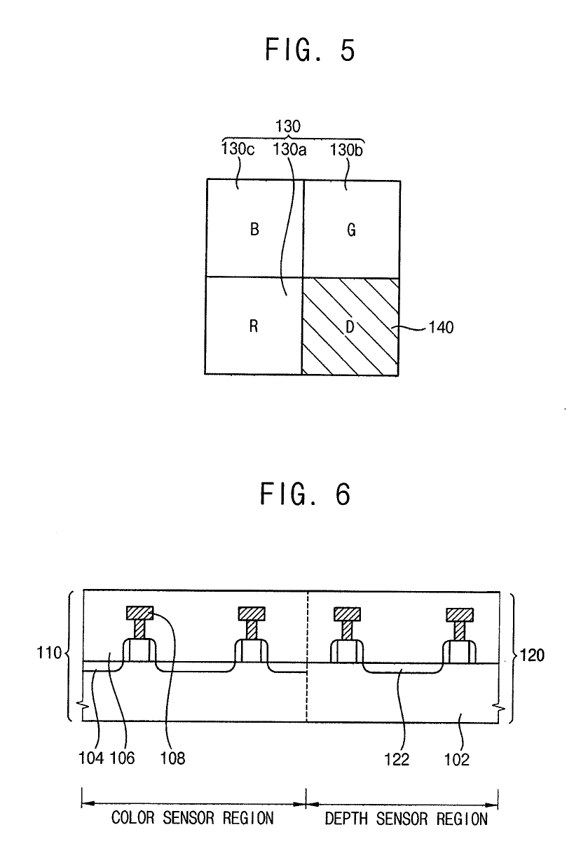

FIG. 1 is a diagram illustrating a three-dimensional color image sensor in accordance with a first embodiment of the present inventive concept. FIG. 2 is a cross-sectional view of a three-dimensional color image sensor illustrated in FIG. 1. FIG. 3 is a graph illustrating spectrum characteristics of filters included in a three-dimensional color image sensor illustrated in FIG. 1. FIG. 4 is a perspective view of a near-infrared cut filter included in a three-dimensional color image sensor illustrated in FIG. 1. FIG. 5 is a diagram illustrating an arrangement of filters included in a three-dimensional color image sensor illustrated in FIG. 1.

Referring to FIGS. 1 and 2, a three-dimensional color image sensor 100 includes an image sensor 160 and a rejection filter 150.

The image sensor 160 includes color sensors 110 and depth sensors 120. The image sensor 160 may further include different filters 114, 130 and 140 respectively formed on the color sensors 110 and the depth sensors 120. The rejection filter 150 may be spaced apart from the image sensor 160.

Hereinafter, the image sensor 160 will be described in detail.

The image sensor 160 is formed on a substrate 102 including an active pixel region and a logic region. The color sensors 110 and the depth sensors 120 may be alternately formed on the active pixel region of the substrate 102, and logic circuits may be formed on the logic region of the substrate 102.

The color sensors 110 formed on a color sensor region of the active pixel region may convert incident light into an electrical signal.

For example, each color sensor 110 may include a first photodiode 104 that generates photocharge in response to the incident light, a transfer transistor that transfers the photocharge from the first photodiode 104 to a floating diffusion region, a reset transistor that periodically resets the floating diffusion region, a drive transistor that serves as a source follower buffer amplifier and buffers a signal corresponding to the photocharge accumulated in the floating diffusion region, and a select transistor that selects a sensor as a switch. The first photodiode 104, the transfer transistor, the reset transistor, the drive transistor and the select transistor may be formed on the color sensor region of the substrate 102. Further, conductive lines 108 may be formed on the color sensor region of the substrate 102 to electrically connect the transistors, and a dielectric layer 106 covering the transistors may be formed on the color sensor region of the substrate 102.

The depth sensors 120 may be formed on a depth sensor region of the active pixel region. The depth sensors 120 may convert incident near-infrared light into an electrical signal. The near-infrared light may have a wavelength ranging from about 800 nm to about 900 nm. For example, the depth sensors 120 may use near-infrared light having a wavelength ranging from about 830 nm to about 870 nm as a light source.

For example, each depth sensor 120 may include a second photodiode 122 that generates photocharge in response to the near-infrared light, and transistors that transfer charges generated in the second photodiode 122 and amplify a signal corresponding to the charges. Conductive lines may be formed on the depth sensor region of the substrate 102 to electrically connect the transistors, and a dielectric layer 106 covering the transistors may be formed on the depth sensor region of the substrate 102.

An upper surface of the dielectric layer 106 formed on the color sensor region and the depth sensor region may be substantially flat. The thickness of the dielectric layer 106 formed on the color sensor region may be substantially the same as or different from the thickness of the dielectric layer 106 formed on the depth sensor region. To increase the intensity of light incident on the first and second photodiodes 104 and 122, the dielectric layer 106 may have a high light transmittance.

A near-infrared (NIR) cut filter 114 may be formed corresponding to the color sensors 110. The NIR cut filter 114 may block the near-infrared light having the wavelength ranging from about 800 nm to about 900 nm.

The NIR cut filter 114 may have a photonic crystal structure including at least two materials having different refractive indexes. The photonic crystal structure may be periodic in space. For example, the photonic crystal structure may be two-dimensionally periodic.

The NIR cut filter 114 may include first patterns 114a that are periodically arranged, and a second pattern 114b that fills spaces between the first patterns 114a with a material having a refractive index different from a material of the first patterns 114a. One of the first patterns 114a and the second pattern 114b may be formed of a semiconductor material, and the other may be formed of a semiconductor oxide material. The NIR cut filter 114 may have beneficial thermal resistance and durability.

An upper surface of the NIR cut filter 114 may be substantially flat. The thickness of the first patterns 114a may be substantially the same as the thickness of the second pattern 114b.

For example, the first embodiment, the first patterns 114a may have pillar shapes, and the first patterns 114a may be formed of a silicon material. The first patterns 114a may have, for example, rectangular parallelepiped shapes as illustrated in FIG. 4. The silicon material may include, for example, polysilicon, amorphous silicon, single crystal silicon, etc. The second pattern 114b may be formed of, for example, silicon oxide. For example, the NIR cut filter 114 may have a structure where silicon pillars are periodically arranged in a silicon oxide matrix.

In FIG. 3, 20a represents a spectral transmittance of the NIR cut filter 114. As illustrated in FIG. 3, the NIR cut filter 114 may be designed to block light having a wavelength ranging from about 700 nm to about 900 nm. The transmittance of the NIR cut filter 114 may be adjusted by changing height h, length d and pitch p of the first patterns 114a. For example, in a case where the first patterns 114a are formed of the silicon material, the height h of the first patterns 114a may range from about 100 nm to about 150 nm, the length d of the first patterns 114a may range from about 150 nm to about 250 nm, and the pitch p of the first patterns 114a may range from 300 nm to about 500 nm.

A color filter 130 is formed on the NIR cut filter 114. The color filter 130 may selectively transmit visible light. The color filter 130 may include red color filter patterns 130a, green color filter patterns 130b and blue color filter patterns 130c. The color filter 130 may be formed of a polymer material including, for example, a color pigment.

In FIG. 3, 10a represents a spectral transmittance of the color filter 130. As illustrated in FIG. 3, the color filter 130 may selectively transmit the visible light having a wavelength ranging from about 400 nm to about 700 nm. The color filter 130 may be formed corresponding to the color sensors 110 to provide a color image.

A NIR band pass filter 140 is formed corresponding to the depth sensors 120. In FIG. 3, 40a represents a spectral transmittance of the NIR band pass filter 140. As illustrated in FIG. 3, the NIR band pass filter 140 may selectively transmit light having a wavelength ranging from about 750 nm to about 870 nm. The NIR band pass filter 140 may have a stacked structure where at least two materials having different refractive indexes are alternately formed. The materials included in the NIR band pass filter 140 may be a semiconductor material and an oxide of the semiconductor material. For example, the NIR band pass filter 140 may have a multi-layer structure where a silicon layer 140a and a silicon oxide layer 140b are alternately stacked. The silicon layer 140a may be formed of, for example, polysilicon, amorphous silicon, single crystal silicon, etc.

The multi-layer structure of the NIR band pass filter 140 may include three through ten layers. The multi-layer structure may have a thickness ranging from about 200 nm to about 1,000 nm, and each layer included in the multi-layer structure may have a thickness lower than about 300 nm. The number of the stacked layers and the thickness of each layer may be selected from the range described above to selectively transmit light having a wavelength ranging from about 750 nm to about 870 nm.

As described above, the NIR band pass filter 140 has a small number of layers, and each layer included in the NIR band pass filter 140 is thin. Accordingly, the NIR band pass filter 140 may have high transmittance and low light loss, and crosstalk may be reduced. Further, as the silicon layer 140a and the silicon oxide layer 140b included in the NIR band pass filter 140 may be readily patterned using a photo etching process, the NIR band pass filter 140 may be suitable for an on-chip optical filter formed on a semiconductor device.

As illustrated in FIG. 5, the color filter 130 and the NIR band pass filter 140 may be alternately distributed in the active pixel region of the image sensor 160. The color filter 130 and the NIR band pass filter 140 may be disposed adjacent to each other. The array of the color filter 130 and the NIR band pass filter 140 illustrated in FIG. 5 may be repeatedly disposed throughout the active pixel region of the image sensor 160.

A first microlens 142 is formed on the color filter 130. The first microlens 142 may concentrate the incident light on the first photodiode 104. In some embodiments, a second microlens may be formed on the NIR band pass filter 140.

As described above, the image sensor 160 included in the three-dimensional color image sensor 100 according to the first embodiment may include the color sensors 110 for providing color image, the depth sensors 120 for providing depth information, and filter structures respectively corresponding to the color sensors 110 and the depth sensors 120, which are integrated within a single chip.

The rejection filter 150 is formed over the image sensor 160. To allow the visible light and the near-infrared light to enter the color sensors 110 and the depth sensors 120, the rejection filter 150 may block a portion of the incident light. In the first embodiment, the rejection filter 150 may transmit light having a wavelength longer than the lower limit of the visible light wavelength and shorter than the upper limit of the near-infrared light wavelength. In FIG. 3, 50a represents a spectral transmittance of the rejection filter 150. As illustrated in FIG. 3, the rejection filter 150 may transmit light having a wavelength ranging from about 400 nm to about 900 nm.

The rejection filter 150 may have a stacked structure where layers of materials having different refractive indexes are alternately stacked. For example, a silicon oxide layer 150a and a titanium oxide layer 150b may be alternately stacked in the rejection filter 150. The transmittance of the rejection filter 150 may be determined according to thicknesses of the silicon oxide layer 150a and the titanium oxide layer 150b. Accordingly, the rejection filter 150 may be adjusted to transmit light of desired wavelengths.

For example, the rejection filter 150 may include thirty through fifty stacked layers where the silicon oxide layer 150a and the titanium oxide layer 150b are alternately stacked. The rejection filter 150 may have a thickness more than about 3 μm. Since the rejection filter 150 is separated from the image sensor 160, the image sensor 160 may be implemented with a single chip although the rejection filter 150 is thick and has a large number of stacked layers.

As illustrated in FIG. 1, the three-dimensional color image sensor 100 may further include a lens module 170 disposed over the rejection filter 150. The lens module 170 may have lenses for concentrating light on the image sensor 160. The rejection filter 150 and the lens module 170 may be mounted in a mounting module 180 and may be spaced apart from the image sensor 160.

As described above, in the first embodiment, filter structures having different configurations are disposed on the color sensors 110 and the depth sensors 120, respectively. Accordingly, lights of different wavelengths may enter corresponding regions. Further, by using the filter structures, the three-dimensional color image sensor 100 providing the three-dimensional color image may be implemented within a single chip.

FIGS. 6 through 10 are cross-sectional views for illustrating a method of manufacturing a three-dimensional color image sensor illustrated in FIG. 2.

Referring to FIG. 6, a substrate 102 including an active pixel region is provided. A color sensor region and a depth sensor region may be distributed throughout the active pixel region, and may be disposed adjacent to each other.

Color sensors 110 are formed on a color sensor region of the substrate 102. For example, a first photodiode 104 may be formed and doped with impurities in the color sensor region of the substrate 102. A transfer transistor, a reset transistor, a drive transistor and a select transistor may be formed on the substrate 102. A dielectric layer 106 covering the first photodiode 104, the transfer transistor, the reset transistor, the drive transistor and the select transistor may be formed, and conductive lines 108 electrically connecting the transistors may be formed in the dielectric layer 106.

Depth sensors 120 are formed on a depth sensor region of the substrate 102. For example, a second photodiode 102 may be formed to generate photocharges in response to near-infrared light, and transistors may be formed to transfer charges generated in the second photodiode 122 and to amplify a signal corresponding to the charges. The dielectric layer 106 covering the transistors may be formed, and the conductive lines 108 electrically connecting the transistors may be formed in the dielectric layer 106.

Additionally, logic circuits may be formed in a logic region of the substrate 102.

Accordingly, the color sensors 110 are formed on the color sensor region of the substrate 102, and the depth sensors 120 are formed on the depth sensor region of the substrate 102. The color sensors 110 and the depth sensors 120 may be disposed adjacent to each other.

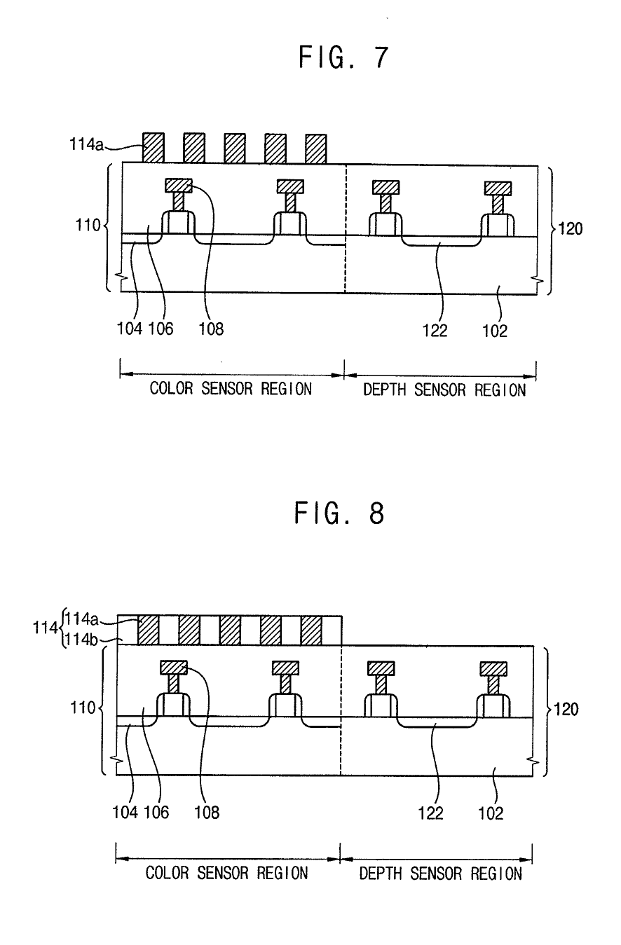

Referring to FIG. 7, a first silicon layer may be formed on the dielectric layer 106. The first silicon layer may be formed of a silicon material, such as, for example, polysilicon, amorphous silicon, single crystal silicon, etc. A first etching mask pattern may be formed on the first silicon layer, and the first silicon layer may be etched using the first etching mask pattern. Accordingly, first patterns 114a having pillars of rectangular parallelepiped shape may be formed corresponding to the color sensors 110.

For example, the length of each side of the upper surface of each first pattern 114a may range from about 150 nm to about 250 nm. The pitch of the first patterns 114a may range from about 300 nm to about 500 nm. The height of the first patterns 114a may range from about 100 nm to about 150 nm.

Referring to FIG. 8, a silicon oxide layer is formed to cover the first patterns 114a and to fill spaces between the first patterns 114a. Subsequently, an upper portion of the silicon oxide layer is removed to expose the upper surface of the first patterns 114a. Such a removal may be performed using, for example, a chemical mechanical planarization process or an etch-back process.

A second etching mask pattern is formed exposing the silicon oxide layer on the depth sensors 120. The second pattern 114b may be formed by, for example, removing the silicon oxide layer on the depth sensors 120 using the second etching mask pattern. Alternatively, to simplify manufacturing processes, the second etching mask pattern may not be formed, and the silicon oxide layer on the depth sensors 120 may not be removed.

Accordingly, as illustrated in FIG. 4, a NIR cut filter 114 including a silicon pillar array that is periodically arranged in a silicon oxide matrix is formed.

Referring to FIG. 9, a multi-layer structure is formed by alternately stacking a silicon layer 140a and a silicon oxide layer 140b on the NIR cut filter and the dielectric layer 106.

The multi-layer structure may have three through ten layers, and may have a thickness ranging from about 200 nm to about 1,000 nm. Each of the silicon layer 140a and the silicon oxide layer 140b may have a thickness lower than about 300 nm.

The number of the stacked layers and the thickness of each layer may be selected from the range described above to selectively transmit light having a wavelength ranging from about 750 nm to about 870 nm. For example, a spectra simulation system may be used to determine the thickness of each layer.

A third etching mask pattern is formed exposing the multi-layer structure on the NIR cut filter 114. The multi-layer structure on the NIR cut filter 114 is removed using the third etching mask pattern. Accordingly, a NIR band pass filter 140 having a multi-layer structure is formed on the depth sensors 120.

Although it is described above that the NIR cut filter 114 is formed after the NIR band pass filter 140 is formed, the NIR cut filter 114 may be formed before the NIR band pass filter 140 is formed in some embodiments.

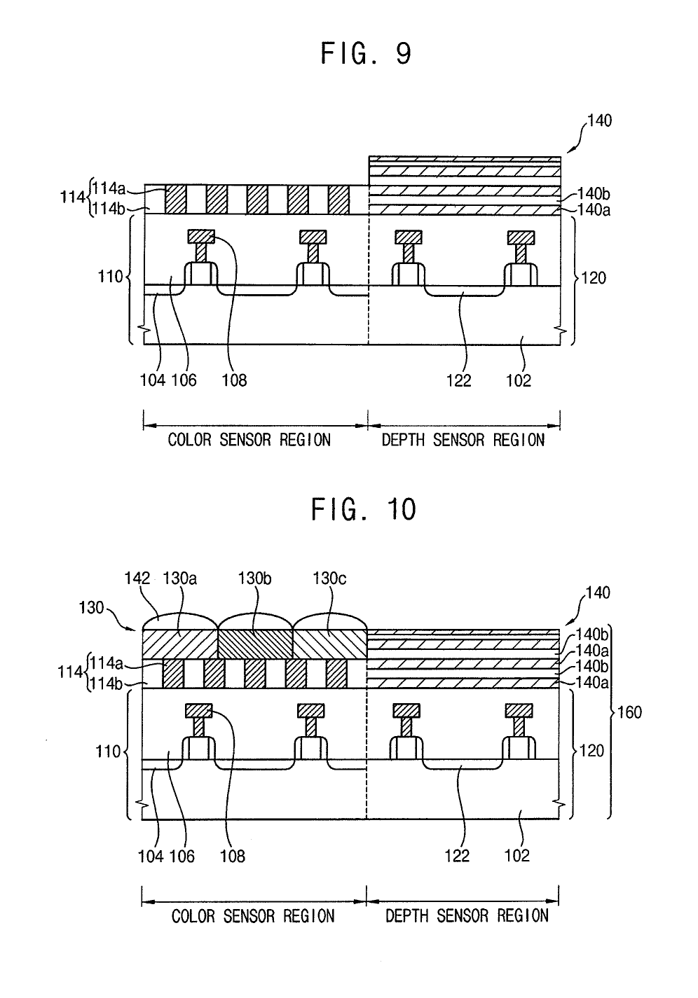

Referring to FIG. 10, a color filter 130 is formed on the NIR cut filter 114.

To form the color filter 130, a first photoresist layer including a red pigment may be coated. A photolithography process may be performed to remove the first photoresist layer except for a region corresponding to red sensors of the color sensors 110. Accordingly, red color filter patterns 130a for transmitting light in a red wavelength band may be formed.

A second photoresist layer including a green pigment may be coated. A photolithography process may be performed to remove the second photoresist layer except for a region corresponding to green sensors of the color sensors 110. Accordingly, green color filter patterns 130b for transmitting light in a green wavelength band may be formed.

A third photoresist layer including a green pigment may be coated. In some embodiments, the third photoresist layer may further include a green dye. A photolithography process may be performed to remove the third photoresist layer except for a region corresponding to blue sensors of the color sensors 110. Accordingly, blue color filter patterns 130c for transmitting light in a blue wavelength band may be formed.

By such a manner, the color filter 130 may be formed including the red patterns 130a, the green patterns 130b and the blue patterns 130c. The order of forming the red patterns 130a, the green patterns 130b and the blue patterns 130c may be varied.

Subsequently, a first microlens 142 is formed on the color filter 130. The first microlens 142 may be formed of a photoresist material. For example, a photoresist layer may be coated on the color filter 130 and the NIR band pass filter 140, and a lens pattern may be formed on the color filter 130 by an exposure and development process. After that, the first microlens 142 having a convex surface may be formed by allowing the lens pattern to reflow using a heat treatment at a temperature of about 200° C.

Accordingly, the image sensor 160 may be formed including the color sensors 110 and the depth sensors 120.

Referring again to FIG. 2, a rejection filter 150 may be formed independently of the image sensor 160. The rejection filter 150 may transmit light having a wavelength ranging from about 400 nm to about 900 nm. The rejection filter 150 may be formed by alternately stacking layers having different refractive indexes. For example, a silicon oxide layer 150a and a titanium oxide layer 150b may be alternately stacked with different thicknesses to form the rejection filter 150.

The refractive indexes, extinction coefficients and/or the thicknesses of the stacked layers may be adjusted to transmit light of desired wavelengths. For example, a spectra simulation system may be used to determine the thickness of each stacked layer included in the rejection filter 150.

The rejection filter 150 may be mounted corresponding to the color filter 130 and the NIR band pass filter 140. A lens module 170 may be mounted corresponding to the rejection filter 150. The rejection filter 150 and the lens module 170 may be mounted by a mounting module 180.

Accordingly, a three-dimensional color image sensor 100 is manufactured.

Hereinafter, a spectrum characteristic of a NIR band pass filter included in a three-dimensional color image sensor according to a first embodiment will be described below.

### Sample 1

A NIR band pass filter included in a three-dimensional color image sensor may be formed by the method described above in accordance with the first embodiment of the present inventive concept.

For example, a glass substrate for test is provided, and a first amorphous silicon layer, a silicon oxide layer and a second amorphous silicon layer are formed. The NIR band pass filter including the three layers may have a thickness of about 545 nm. The thickness of each layer is described in table 1.

TABLE 1

| Layer | Material | Thickness (um) |
|---|---|---|
| 1 | Si | about 200 |
| 2 | SiO₂ | about 145 |
| 3 | Si | about 200 |

### Spectrum Characteristic Measurement

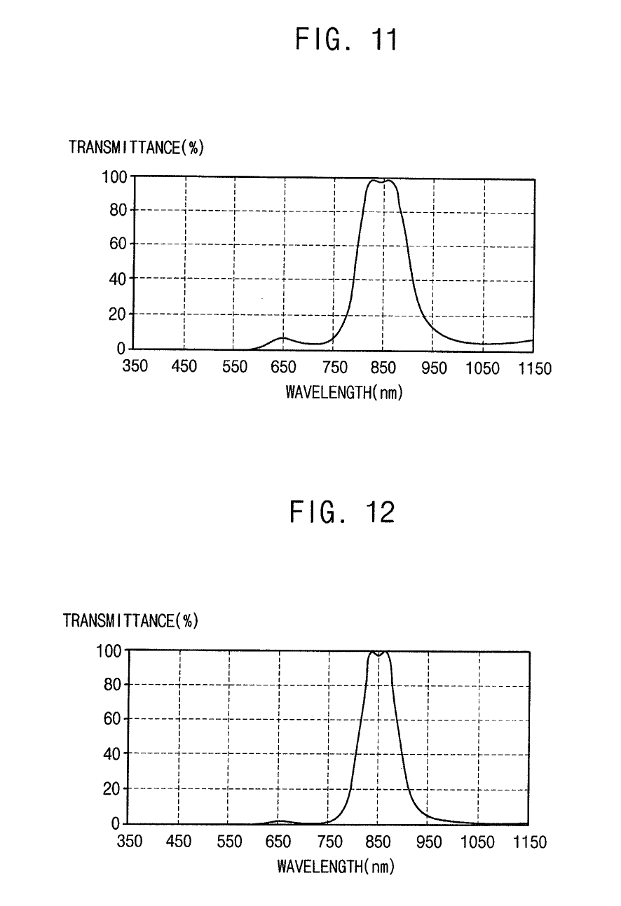

FIG. 11 illustrates a spectrum characteristic of a NIR band pass filter of a first sample.

Referring to FIG. 11, the NIR band pass filter of the first sample may have a transmittance more than about 80% for light having a wavelength ranging from about 830 nm to about 870 nm, and may have a transmittance less than about 20% for light having a wavelength longer than about 950 nm. Thus, the NIR band pass filter of the first sample is suitable for the NIR band pass filter included in the three-dimensional color image sensor according to the first embodiment.

### Sample 2

A NIR band pass filter included in a three-dimensional color image sensor may be formed by the method described above in accordance with the first embodiment of the present inventive concept.

For example, a glass substrate for test is provided, and an amorphous silicon layer and a silicon oxide layer are alternately stacked to form the NIR band pass filter including seven layers. The NIR band pass filter including the seven layers may have a thickness of about 650 nm. The thickness of each layer is described in table 2.

TABLE 2

| Layer | Material | Thickness (um) |
|---|---|---|
| 1 | Si | about 199 |
| 2 | SiO₂ | about 172 |
| 3 | Si | about 60 |
| 4 | SiO₂ | about 77 |
| 5 | Si | about 17 |
| 6 | SiO₂ | about 80 |
| 7 | Si | about 45 |

### Spectrum Characteristic Measurement

FIG. 12 illustrates a spectrum characteristic of a NIR band pass filter of a second sample.

Referring to FIG. 12, the NIR band pass filter of the second sample may have a transmittance more than about 90% for light having a wavelength ranging from about 830 nm to about 870 nm, and may have a transmittance less than about 10% for light having a wavelength longer than about 950 nm. Thus, the NIR band pass filter of the second sample is suitable for the NIR band pass filter included in the three-dimensional color image sensor according to the first embodiment.

### Embodiment 2

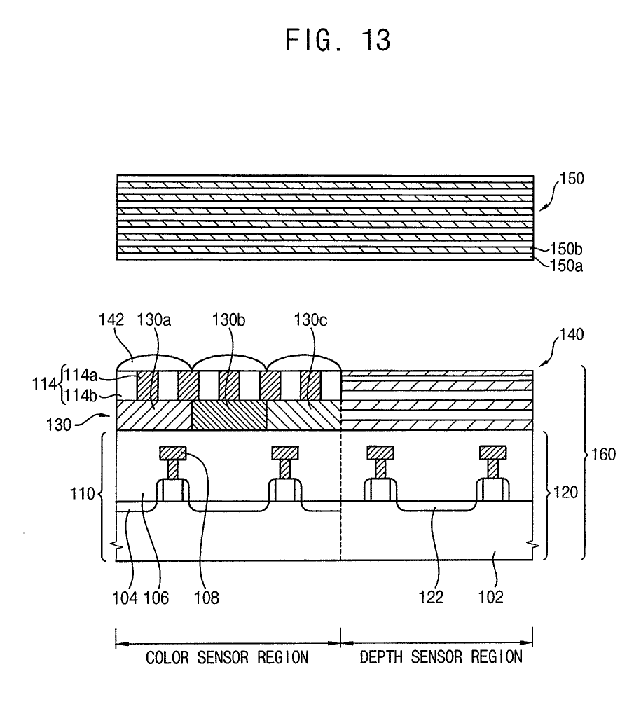

FIG. 13 is a cross-sectional view of a three-dimensional color image sensor in accordance with a second embodiment of the present inventive concept.

As illustrated in FIG. 13, a three-dimensional color image sensor according to the second embodiment is substantially similar to the three-dimensional color image sensor according to the first embodiment except for the arrangement of filters on color sensors 110. Unlike the first embodiment, a NIR cut filter 114 may be formed on a color filter 130 in the second embodiment.

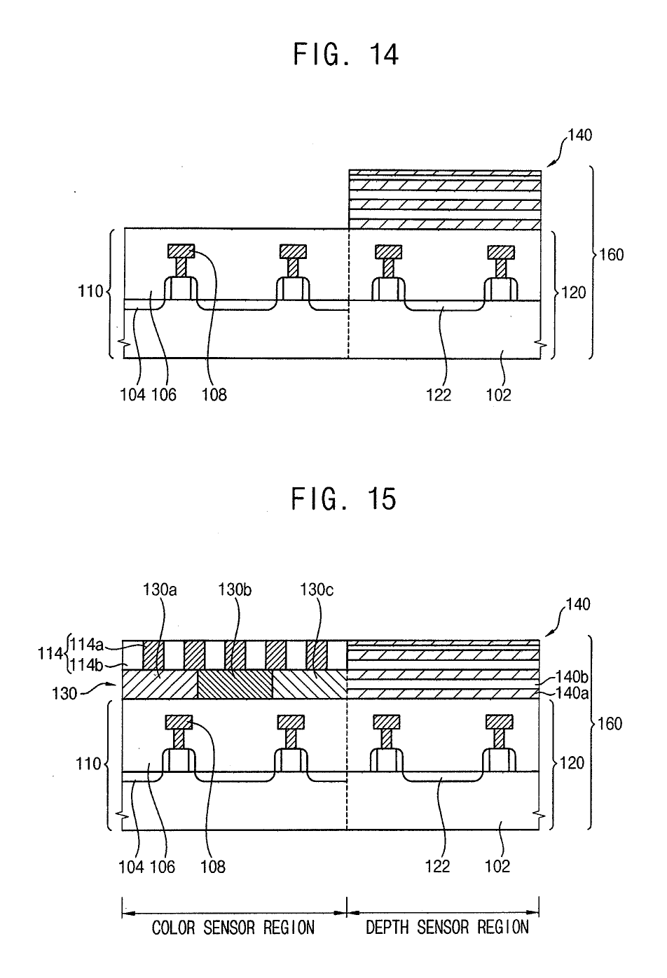

FIGS. 14 and 15 are cross-sectional views for illustrating a method of manufacturing a three-dimensional color image sensor illustrated in FIG. 13.

Referring to FIG. 14, color sensors 110 and depth sensors 120 are formed on a substrate.

A multi-layer structure is formed by alternately stacking a silicon layer 140a and a silicon oxide layer 140b on the color sensors 110 and the depth sensors 120. A NIR band pass filter 140 may be formed on the depth sensors 120 by patterning the multi-layer structure. The NIR band pass filter 140 may be formed by the processes described above with reference to FIG. 9.

Referring to FIG. 15, a color filter 130 is formed on the NIR band pass filter and the color sensors 110. The color filter 130 may be formed by the processes described above with reference to FIG. 10.

A NIR cut filter 114 is formed on the color filter 130. The NIR cut filter 114 may be formed by the processes described above with reference to FIGS. 7 and 8.

Subsequently, as illustrated in FIG. 13, a first microlens 142 is formed on the color filter 130. Accordingly, the image sensor 160 may be formed. Further, a rejection filter 150 may be formed independently of the image sensor 160.

As described above, in the three-dimensional color image sensor illustrated in FIG. 13, the NIR cut filter 114 may be formed after the color filter 130 is formed.

### Embodiment 3

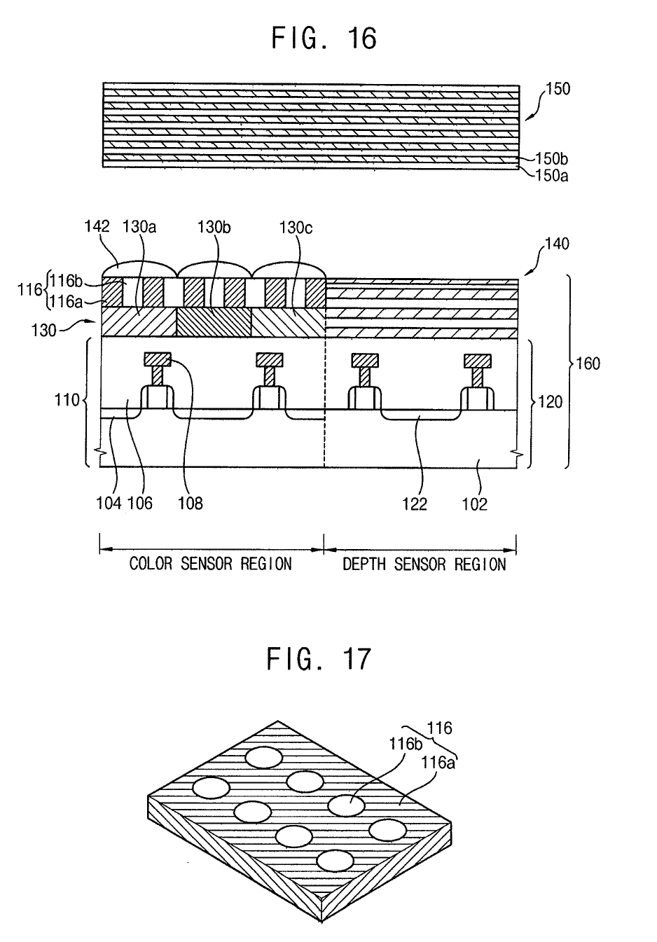

FIG. 16 is a cross-sectional view of a three-dimensional color image sensor in accordance with a third embodiment of the present inventive concept. FIG. 17 is a perspective view of a NIR cut filter included in a three-dimensional color image sensor illustrated in FIG. 16.

As illustrated in FIG. 16, a three-dimensional color image sensor according to the third embodiment is substantially similar to the three-dimensional color image sensor according to the first embodiment except for a NIR cut filter 116 on color sensors 110.

Referring to FIGS. 16 and 17, the NIR cut filter 116 formed on the color sensors 110 may a photonic crystal structure where at least two materials having different refractive indexes are periodically arranged.

In the third embodiment, the NIR cut filter 116 may include first patterns 116b that are periodically arranged, and a second pattern 116a that fills spaces between the first patterns 116b with a material having a refractive index different from a material of the first patterns 116b. The first patterns 116b may be formed of, for example, a silicon oxide material, and the second pattern 116a may be formed of, for example, a silicon material. That is, the NIR cut filter 116 may have a structure where silicon oxide pillars are periodically arranged in a silicon matrix.

The NIR cut filter 116 may be designed to block light having a wavelength ranging from about 700 nm to about 900 nm. The transmittance of the NIR cut filter 116 may be adjusted by changing height, diameter and pitch of the first patterns 116b.

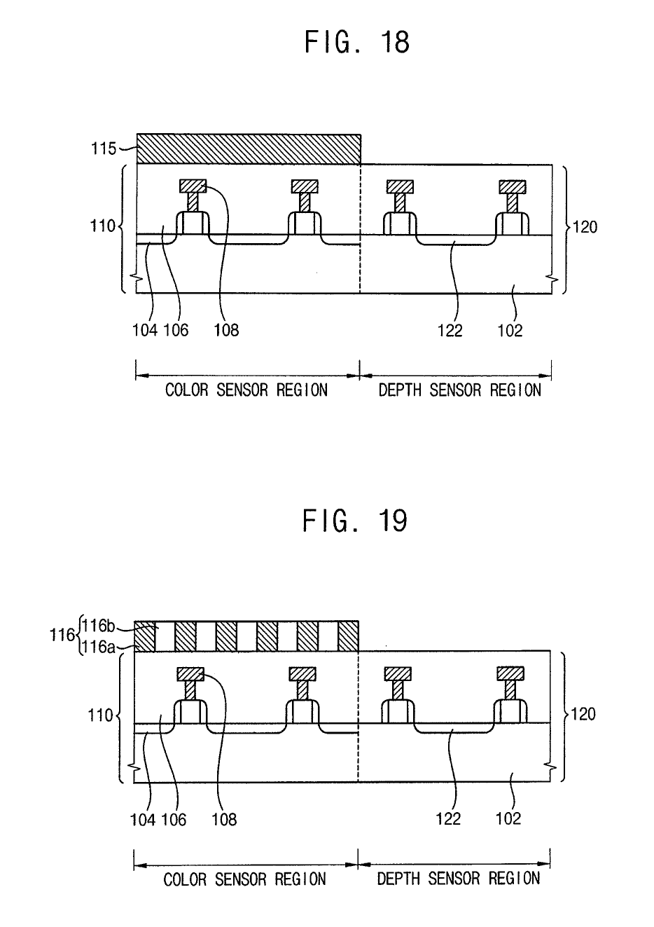

FIGS. 18 and 19 are cross-sectional views for illustrating a method of manufacturing a three-dimensional color image sensor illustrated in FIG. 16.

Referring to FIG. 18, color sensors 110 and depth sensors 120 are formed on a substrate 102. A first silicon layer 115 is formed on the color sensors 110 and the depth sensors 120.

Referring to FIG. 19, an etching mask pattern may be used to form openings in the first silicon layer 115. The etching mask pattern may expose the first silicon layer 115 on the depth sensors 120, and may further expose the openings that are periodically arranged over the color sensors 110.

A second pattern 116a including holes is formed by etching the first silicon layer 115 using the etching mask pattern. Subsequently, the holes are filled with a silicon oxide material. The silicon oxide material formed on the second pattern 116a may be removed to expose the upper surface of the second pattern 116a. Accordingly, first patterns 116b of the silicon oxide material having pillar shapes are formed.

Accordingly, the NIR cut filter 116 illustrated in FIG. 17 is formed. The transmittance of the NIR cut filter 116 may be adjusted by changing height, diameter and pitch of the first patterns 116b.

A three-dimensional color image sensor illustrated in FIG. 16 may be formed by performing the processes described above with reference to FIGS. 2, 9 and 10.

### Embodiment 4

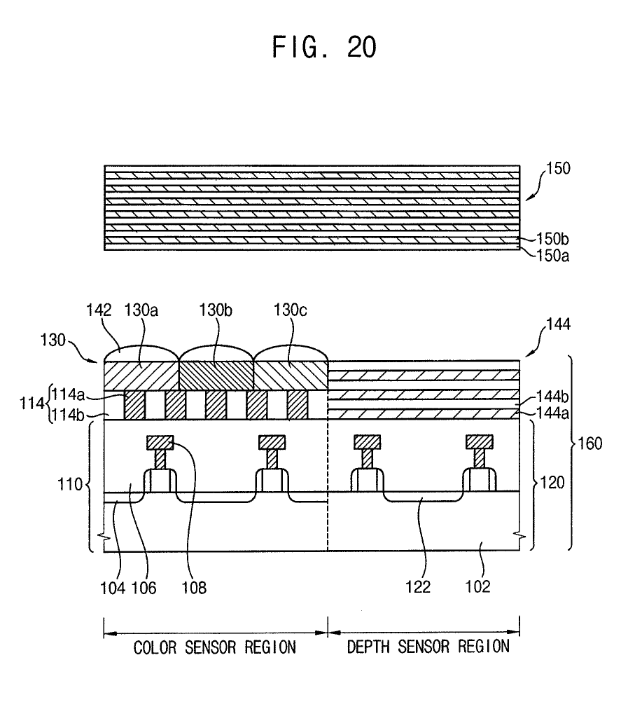

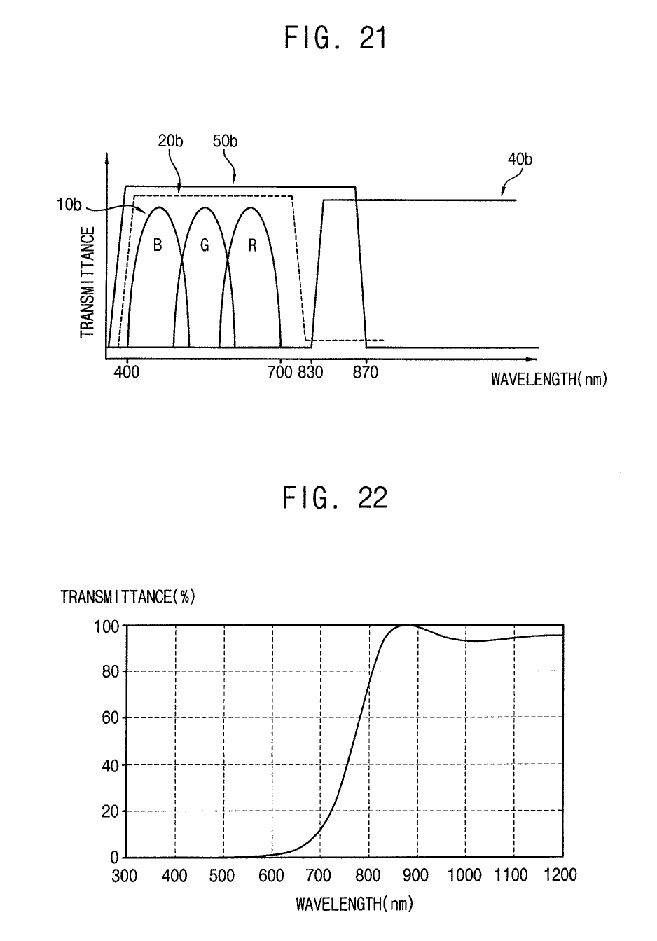

FIG. 20 is a cross-sectional view of a three-dimensional color image sensor in accordance with a fourth embodiment of the present inventive concept. FIG. 21 is a graph illustrating spectrum characteristics of filters included in a three-dimensional color image sensor illustrated in FIG. 20.

As illustrated in FIG. 20, arrangements and configurations of color sensors 110, depth sensors 120, a rejection filter 150, a NIR cut filter 114 and a color filter 130 included in a three-dimensional color image sensor according to a fourth embodiment may be substantially similar to those of the three-dimensional color image sensor according to the first embodiment. However, a spectrum characteristic of a filter formed on the depth sensors 120 according to the fourth embodiment may be different from that of the first embodiment.

Referring to FIGS. 20 and 21, a long wave pass filter 144 is formed on the depth sensors 120. The long wave pass filter 144 may transmit light having a wavelength longer than about 700 nm. The long wave pass filter 144 may have a stacked structure where at lest two materials having different refractive indexes are alternately formed. For example, the long wave pass filter 144 may have a multi-layer structure where a silicon layer 144a and a silicon oxide layer 144b are alternately stacked.

The multi-layer structure of the long wave pass filter 144 may have three through ten stacked layers. The multi-layer structure may have a thickness of about 700 nm, and each layer in the multi-layer structure may have a thickness lower than about 300 nm. The number of the stacked layers and the thickness of each layer may be selected from the range described above to selectively transmit the light having the wavelength longer than about 700 nm.

That is, in the fourth embodiment, only the number of the stacked layers and the thickness of each layer, which are selected to transmit a long wave, may be different from those of the first embodiment.

The method of manufacturing the three-dimensional color image sensor according to the fourth embodiment may be substantially similar to that of the first embodiment except for forming the long wave pass filter 144 instead of a NIR band pass filter.

The long wave pass filter 144 may be formed by alternately stacking and patterning the silicon layer 144a and the silicon oxide layer 144b. The long wave pass filter 144 may have a multi-layer structure where three through ten layers are stacked. The multi-layer structure may have a thickness ranging from about 200 nm to about 1,000 nm, and each of the silicon layer 144a and the silicon oxide layer 144b may have a thickness lower than about 300 nm.

The number of the stacked layers and the thickness of each layer may be selected from the range described above to selectively transmit light having a wavelength longer than about 700 nm. For example, a spectra simulation system may be used to determine the thickness of each layer.

Hereinafter, a spectrum characteristic of a long wave pass filter included in a three-dimensional color image sensor according to a fourth embodiment will be described below.

### Sample 3

A long wave pass filter included in a three-dimensional color image sensor may be formed by the method described above in accordance with the fourth embodiment of the present inventive concept.

For example, a glass substrate for test is provided, and an amorphous silicon layer and a silicon oxide layer are alternately stacked to form the long wave pass filter including five layers. The long wave pass filter including the five layers may have a thickness of about 250 nm. The thickness of each layer is described in table 3.

TABLE 3

| Layer | Material | Thickness (um) |
|---|---|---|
| 1 | Si | about 15 |
| 2 | SiO₂ | about 95 |
| 3 | Si | about 30 |
| 4 | SiO₂ | about 95 |
| 5 | Si | about 15 |

### Spectrum Characteristic Measurement

FIG. 22 is illustrates a spectrum characteristic of a long wave pass filter of a third sample.

Referring to FIG. 22, the long wave pass filter of the third sample may have a transmittance more than about 80% for light having a wavelength longer than about 830 nm. Thus, the long wave pass filter of the third sample is suitable for the long wave pass filter included in the three-dimensional color image sensor according to the fourth embodiment.

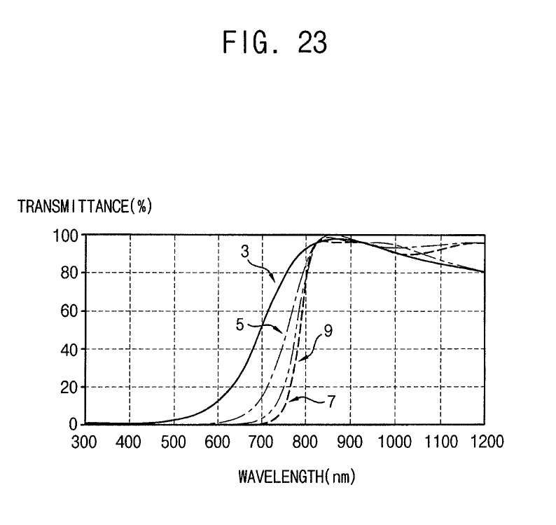

FIG. 23 is a graph illustrating spectrum characteristics of long wave pass filters of which the numbers of layers are different from each other.

Referring to FIG. 23, a long wave pass filter having three through nine stacked layers may selectively transmit light having a wavelength longer than 700 nm. The long wave pass filter may have a multi-layer structure where a silicon layer and a silicon oxide layer are alternately formed.

In other embodiments, the NIR cut filter 114 of the fourth embodiment may alternatively be formed to have a structure where silicon oxide pillars are periodically arranged in a silicon matrix. In this case, the NIR cut filter may be substantially similar to that of the third embodiment.

In still other embodiments, the NIR cut filter 114 of the fourth embodiment may alternatively be formed after the color filter 130 is formed. In this case, the order of forming the color filter 130 and the NIR cut filter 114 may be substantially similar to that of the second embodiment.

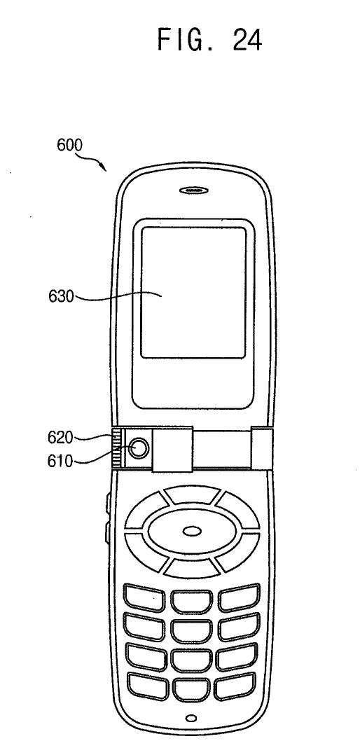

FIG. 24 is a diagram illustrating a mobile phone including a three-dimensional color image sensor that provides depth information as well as image information.

Compared to a typical mobile phone, a mobile phone 600 according to example embodiments may further include a rejection filter in a camera lens module 610 and an image sensor 620 that provides depth information as well as image information. Thus, the image information and the depth information can be simultaneously displayed on a screen 630. The mobile phone 600 can obtain and display a three-dimensional color image.

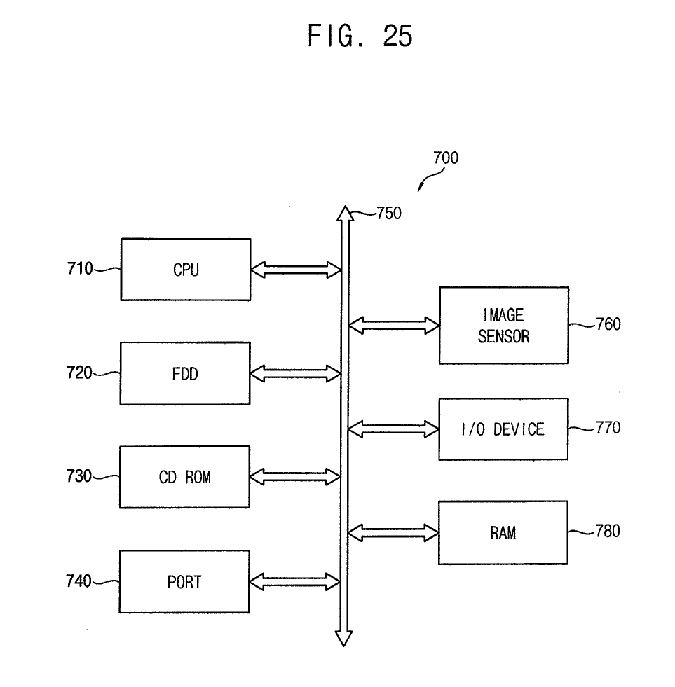

FIG. 25 is a block diagram illustrating a system including a three-dimensional color image sensor that provides depth information as well as image information.

Referring to FIG. 25, a system 700 may include a three-dimensional color image sensor 760 that provides depth information as well as image information. For example, the system 700 may include a computer system, a camera system, a scanner, a navigation system, etc. The system 700 may provide a three-dimensional color image using the three-dimensional color image sensor 760.

For example, the processor-based system 700, such as a computer system, may include a central processing unit (CPU) 710, such as a micro processor, that communicates with an input/output device 770 via a bus 750. The CPU 710 may exchange data with, for example, a floppy disk drive 720, CD ROM drive 730, port 740 and/or RAM 780 via the bus 750. The CPU 710 may control the three-dimensional color image sensor 760 to obtain the three-dimensional color image.

The port 740 may be connected to, for example, a video card, a sound card, a memory card, a USB device, etc., or may be used to communicate with another system.

As described above, in the three-dimensional color image sensor according to example embodiments, lights of different wavelengths may enter corresponding regions by using the filter structures.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. An image sensor, comprising:
a plurality of color sensors and a plurality of depth sensors formed on a substrate;
a near-infrared cut filter and a color filter formed on the color sensors;
a pass filter formed on the depth sensors, the pass filter adapted to transmit light having a wavelength longer than an upper limit of a visible light wavelength, the pass filter having a multi-layer structure wherein a semiconductor material and a semiconductor oxide material are alternately stacked; and
a rejection filter formed over the near-infrared cut filter, the color filter and the pass filter, the rejection filter adapted to transmit light having a wavelength shorter than an upper limit of a near-infrared light wavelength.

2. The image sensor of claim 1, wherein the semiconductor material includes silicon, and
wherein the semiconductor oxide material includes silicon oxide.

3. The image sensor of claim 1, wherein the multi-layer structure includes three through ten layers, and the multi-layer structure has a thickness ranging from about 200 nm to about 1,000 nm.

4. The image sensor of claim 1, wherein each layer included in the multi-layer structure has a thickness lower than about 200 nm.

5. The image sensor of claim 1, wherein the pass filter is adapted to transmit light having a wavelength ranging from about 800 nm to about 900 nm and wherein the rejection filter is adapted to transmit light having a wavelength ranging from about 400 nm to about 900 nm.

6. The image sensor of claim 1, wherein the pass filter is adapted to transmit light having a wavelength longer than about 800 nm.

7. The image sensor of claim 1, wherein the near-infrared cut filter has a photonic crystal structure including at least two materials having different refractive indexes.

8. The image sensor of claim 7, wherein the at least two materials include silicon and silicon oxide.

9. The image sensor of claim 7, wherein the near-infrared cut filter includes:
a silicon pillar array including a plurality of silicon pillars that are periodically arranged; and
a silicon oxide matrix filling spaces between the silicon pillars with silicon oxide.

10. The image sensor of claim 7, wherein the near-infrared cut filter includes:
a silicon oxide pillar array including a plurality of silicon oxide pillars that are periodically arranged; and
a silicon matrix filling spaces between the silicon oxide pillars with silicon.

11. The image sensor of claim 1, wherein the near-infrared cut filter is formed on the color filter.

12. The image sensor of claim 1, wherein the near-infrared cut filter is formed beneath the color filter.

13. A method of manufacturing an image sensor, the method comprising:
forming a plurality of color sensors and a plurality of depth sensors on a substrate;
forming a near-infrared cut filter and a color filter on the color sensors;
forming a pass filter on the depth sensors, the pass filter adapted to transmit light having a wavelength longer than an upper limit of a visible light wavelength, the pass filter having a multi-layer structure wherein a semiconductor material and a semiconductor oxide material are alternately stacked; and
forming a rejection filter over the near-infrared cut filter, the color filter and the pass filter, the rejection filter adapted to transmit light having a wavelength shorter than an upper limit of a near-infrared light wavelength.

14. The method of claim 13, wherein the forming of the pass filter includes:
alternately stacking a silicon layer and a silicon oxide layer on the color sensors and the depth sensors; and
removing the silicon layer and the silicon oxide layer on the color sensors.

15. The method of claim 14, wherein a number of the stacked silicon and the silicon oxide layers is three through ten.

16. The method of claim 14, wherein the pass filter has a thickness ranging from about 200 nm to about 1,000 nm.

17. The method of claim 14, wherein each of the silicon layer and the silicon oxide layer has a thickness lower than about 200 nm.

18. The method of claim 13, wherein the near-infrared cut filter has a photonic crystal structure including at least two materials having different refractive indexes.

19. The method of claim 13, wherein the forming of the near-infrared cut filter includes:
forming a plurality of periodic silicon pillars on the color sensors; and
filling spaces between the silicon pillars with silicon oxide.

20. The method of claim 13, wherein the forming of the near-infrared cut filter includes:
forming a silicon layer on the color sensors;
forming periodic holes in the silicon layer; and
filling the holes with silicon oxide.
